(19) United States
(12) Patent Application Publication
(10) Pub. No.: US 2010/0071624 A1
(43) Pub. Date: Mar. 25, 2010

(54) SUBSTRATE SUPPORT FRAME, AND SUBSTRATE PROCESSING APPARATUS INCLUDING THE SAME AND METHOD OF LOADING AND UNLOADING SUBSTRATE USING THE SAME

(75) Inventor: Yong-Hyun LEE, Gyeonggi-do (KR)

Correspondence Address: HOSOON LEE, 9600 SW OAK ST. SUITE 525, TIGARD, OR, 97223, US

(73) Assignee: Jusung Engineering Co., Ltd., Gyeonggi-do (KR)

(21) Appl. No.: 12/528,327

(22) PCT Filed: Feb. 27, 2008
(86) PCT No.: PCT/KR2008/001152

§ 371 Date: Aug. 24, 2009

(30) Foreign Application Priority Data
Feb. 28, 2007 (KR) 10-2007-0020558

(51) Int. Cl. C23C 16/458

(52) U.S. Cl. 118/729; 118/728

(57) ABSTRACT

A substrate support frame for loading or unloading a substrate on or from a susceptor in a chamber, wherein the substrate support frame is disposed over the susceptor, comprises a body supporting a boundary portion of the substrate; a first opening through a center portion of the body and exposing a center portion of the susceptor; and a second opening corresponding to one side of the body, wherein the substrate is disposed on the body through the second opening to overlap the center portion of the susceptor.

### TECHNICAL FIELD

The present invention relates to a substrate processing apparatus, and more particularly, to a substrate support frame for supporting a substrate in a substrate processing apparatus, and the substrate processing apparatus including and a method of loading and unloading the substrate using the same.

### BACKGROUND ART

For response to exhaustion of fossil fuel and preventing environmental pollution, a clean energy source, e.g., solar energy, has been come into the spotlight. Particularly, the solar cell for converting solar energy into electric energy has been developed rapidly.

In the solar cell that may be amorphous silicon thin layer of PN (positive-negative) junction diode or a PIN (positive-intrinsic-negative) diode on a substrate of silicon wafer or glass, minor carriers excited due to a solar energy are diffused through a PN junction surface and an electromotive force is generated by a voltage difference at both ends of the PN junction diode.

A process of forming an anti-reflective layer and one of P (positive) and N (negative) type semiconductor layers or one of P (positive), I (intrinsic) and N (negative) type amorphous silicon thin films, and a process of etching the layers or the thin film to form a pre-determined pattern are required for forming the solar cell.

Recently, a size of the substrate for the solar cell is increasingly enlarged to improve productivity. FIG. 1 shows a conventional substrate processing apparatus for depositing a thin film on a substrate through a PECVE (plasma enhanced chemical vapor deposition) method.

In FIG. 1, the substrate processing apparatus 10 includes a chamber 11, a susceptor 12, an upper electrode 15, a gas distribution plate 14, a gas supplying pipe 16 and an exhaust hole 18. The susceptor 12 is disposed in an inner space defined by the chamber 11, and a substrate S is loaded on the susceptor 12. Also, the susceptor 12 functions as a counter electrode for the upper electrode 15. The upper electrode 15 is disposed over the susceptor 12 and connected to a RF (radio frequency) power source 17. The gas distribution plate 14 is disposed between the susceptor 12 and the upper electrode 15, and has a plurality of injection holes. The gas distribution plate 14 may be combined with the upper electrode 15 to be fixed to the chamber 11. The gas supplying pipe 16 for supplying a source material into the gas distribution plate 14 penetrates a portion of the upper electrode 15, and remained gases in the chamber 11 is exhausted through the exhaust hole 18 disposed at a bottom portion of the chamber 11.

The susceptor 12 is movable upward and downward depending on a movement of a susceptor supporter 12a extending downward from a central portion of the susceptor 12.

A lift pin 13 runs through the susceptor 12 for loading or unloading the substrate S on or from the susceptor 12. The susceptor 12 moves downward such that the lift pin 13 protrudes from the susceptor 12, and the substrate S is transferred into the chamber 11. And then, the substrate S is disposed onto the lift pin 13, and the susceptor 12 moves upward to load the substrate S on the susceptor 12.

On the Contrary, the susceptor 12 moves downward after finishing a process such that the lift pin 13 pushes up the substrate S from the susceptor 12. As a result, the substrate S is unloaded from the susceptor 12.

### DISCLOSURE OF INVENTION

### Technical Problem

However, there are some problems in the conventional substrate processing apparatus. Generally, the lift pin is formed of a ceramic material. The lift pin functions as a supporter for the substrate during loading and unloading the substrate. When the lift pin supports the substrate with being slanted with respect to the substrate, the lift pin suffers from load of the substrate such that breakage of the lift pin occurs.

Particularly, the substrate for the solar cell is thicker than that for the semiconductor device. In general, since the substrate for the solar cell has the thickness above several millimeters, it has a relatively high weight. When the substrate supported by the lift pin has a relatively high weight, breakage of the lift pin occurs more frequently. Since the breakage of the lift pin requires to be off the apparatus for changing or repairing the lift pin, the productivity decreases.

The breakage problem of the lift pin is not confined to an apparatus for processing a substrate for the solar cell. The breakage of the lift pin occurs in an apparatus for processing a substrate for other purposes.

### Technical Solution

Accordingly, embodiments of the invention is directed to a substrate support frame, and a substrate processing apparatus including and a method of loading and unloading a substrate using the same that substantially obviate one or more of the problems due to limitations and disadvantages of the related art are described.

An object of the embodiments of the invention is to provide a substrate processing apparatus being capable of increasing productivity.

To achieve these and other advantages and in accordance with the purpose of embodiments of the invention, as embodied and broadly described, a substrate support frame for loading or unloading a substrate on or from a susceptor in a chamber, wherein the substrate support frame is disposed over the susceptor, comprises a body supporting a boundary portion of the substrate; a first opening through a center portion of the body and exposing a center portion of the susceptor; and a second opening corresponding to one side of the body, wherein the substrate is disposed on the body through the second opening to overlap the center portion of the susceptor.

In another aspect, a substrate processing apparatus comprises a chamber having an inner space; a susceptor in the inner space of the chamber and being movable upward and downward; an electrode over the susceptor; a gas distribution plate disposed between the susceptor and the electrode and supplying a source material into the inner space of the chamber; and a substrate support frame including first and second openings and disposed over the susceptor, the first opening through a center portion of the substrate support frame and exposing a center portion of the susceptor, the second opening corresponding to one side of the substrate support frame, wherein a substrate is transferred onto the substrate support frame through the second opening, and wherein the substrate is supported by the substrate support frame and pushed up to a processing position with the substrate support frame by the susceptor.

In another aspect, a method of loading the substrate on the susceptor using the substrate processing apparatus comprises disposing the substrate on the substrate support frame, wherein a boundary portion of the substrate contacts the substrate support frame, and a center portion of the substrate corresponds to the first opening; and moving the susceptor upward such that the substrate support frame with the substrate is located at a pre-determined position, wherein when the susceptor moves upward, a center portion of the susceptor contacts the center portion of the substrate through the first opening.

In another aspect, a method of unloading the substrate from the susceptor using the substrate processing apparatus comprises moving the susceptor downward such that the substrate support frame with the substrate is disposed on a frame supporter at an inner sidewall of the chamber to be separated from the susceptor; separating the substrate from the substrate support frame; and transferring the substrate from the chamber into an outside of the chamber.

### ADVANTAGEOUS EFFECTS

In a substrate processing apparatus according to the present invention, there is a substrate support frame contacting a boundary portion of a bottom surface of a substrate. Since the substrate support frame includes a body along the boundary portion and is supported by a frame supporter at an inner sidewall of a chamber, there is no problem such as a breakage of a lift pin in a conventional substrate processing apparatus. Accordingly, productivity is improved.

### BRIEF DESCRIPTION OF THE DRAWINGS

The accompanying drawings, which are included to provide a further understanding of embodiments of the invention and are incorporated in and constitute a part of this specification, illustrate embodiments of the invention and together with the description serve to explain the principles of embodiments of the invention. In the drawings:

FIG. 1 is a cross-sectional view of a conventional substrate processing apparatus;

FIG. 2 is a cross-sectional view of a substrate processing apparatus according to an embodiment of the present invention;

FIG. 3 is a perspective view of a substrate support frame according to an embodiment of the present invention;

FIG. 4 shows a substrate support frame where a substrate is loaded;

FIG. 5 shows a substrate support frame where a substrate is loaded;

FIGS. 6 and 7 are cross-sectional views showing a substrate support frame, where a substrate is loaded, with a frame supporter, respectively;

FIG. 8 is a cross-sectional view of a substrate processing apparatus according to the present invention when a susceptor moves upward;

FIG. 9 is a cross-sectional view showing a contact portion of a susceptor and a substrate support frame;

FIG. 10 is a perspective view of a substrate support frame according to an embodiment of the present invention;

FIG. 11 is a perspective view of a substrate support frame according to an embodiment of the present invention; and

FIG. 12 is a cross-sectional view of a substrate processing apparatus according to an embodiment of the present invention.

### BEST MODE FOR CARRYING OUT THE INVENTION

FIG. 2 is a cross-sectional view of a substrate processing apparatus according to an embodiment of the present invention. As shown in FIG. 2, a substrate processing apparatus 100 includes a chamber 110, a susceptor 120, an upper electrode 160, a gas distribution plate 150, a gas supplying pipe 170 and an exhaust hole 112. The susceptor 120 is disposed in an inner space defined by the chamber 110, and a substrate S is loaded on the susceptor 120. Also, the susceptor 120 functions as a counter electrode for the upper electrode 160. The upper electrode 160 is disposed over the susceptor 120 and connected to a RF (radio frequency) power source 180. The gas distribution plate 150 is disposed between the susceptor 120 and the upper electrode 160, and has a plurality of injection holes 152. The gas distribution plate 150 may be combined with the upper electrode 160 to be fixed to the chamber 110. The gas supplying pipe 170 for supplying a source material into the gas distribution plate 150 penetrates a portion of the upper electrode 160, and remained gases in the chamber 110 is exhausted through the exhaust hole 112 disposed at a bottom portion of the chamber 110.

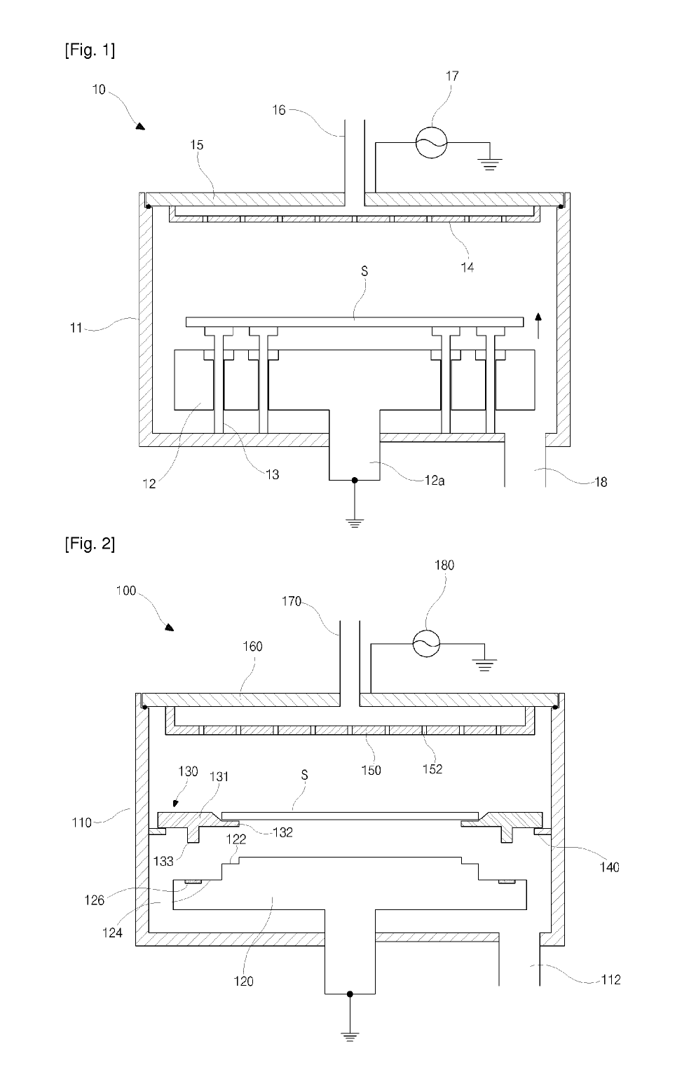

In addition, the substrate processing apparatus 100 includes a substrate support frame 130 on or over the susceptor 120. The lift pin 13 (of FIG. 1) supports the substrate during loading and unloading, while the substrate support frame 130 supports the substrate S in the present invention. On the other hand, the substrate 100 may include not only the substrate support frame 130 but also a lift pin to support the substrate S during loading and unloading the substrate S.

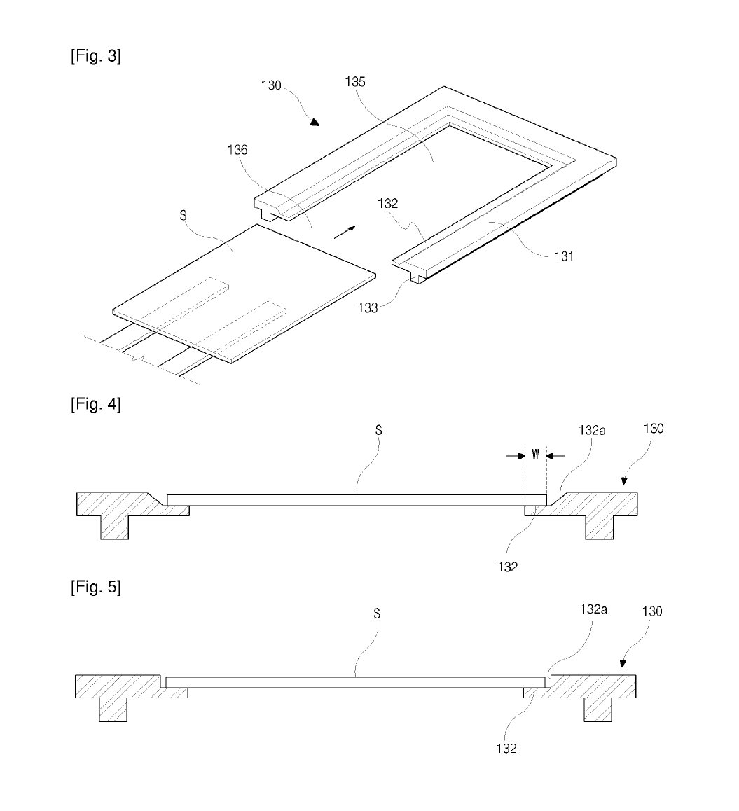

Referring to FIG. 3 with FIG. 2, the substrate support frame 130 includes a body 131 and first and second openings 135 and 136. The first opening 135 is formed on a front surface of the body 131, and the second opening 136 is formed at a side surface of the body 131. The body 131 has a shape corresponding to the substrate S. In FIG. 3, the body 131 has a rectangular shape. When the susceptor 120 moves upward, an upper surface of the susceptor 120 contacts a bottom surface of the substrate S through the first opening 135 to push up the substrate S. Accordingly, a shape of the first opening 135 is determined depending on a shape of the upper surface of the susceptor 120. The substrate S is carried through the second opening 136 by a robot to contact and be supported by the body. The substrate support frame 130 is located for the second opening 136 to correspond to a substrate in/out port (not shown) at a sidewall of the chamber 110. The body 131 may have an edge portion 132, which is dented from an upper surface of the body 131, to efficiently support the substrate S. Namely, an upper surface of the edge portion 132 has a smaller height than that of the body 131. In this case, the substrate contacts not the upper surface of the body 131 but the upper surface of the edge portion 132. When the body 131 has a flat upper surface without the edge portion 132, the substrate S may be mis-located or misaligned onto the body 131. Since the substrate S contacts and is supported by the edge portion 132 of the body 131, the above problems can be prevented. In addition, the substrate support frame 130 has a leg 133 protruding from a bottom surface of the substrate support frame 130 and contacting a portion of the susceptor 120. The leg 133 may be continuous along the body 131. On the other hand, a plurality of legs 133 may be formed to be spaced apart from one another. The leg 133 can be omitted.

The substrate support frame 130 may be formed of anodized aluminum (Al), and there are some advantages. The aluminum has a chemical tolerance to process gases. In addition, the substrate support frame 130 is electrically isolated from the susceptor, which functions as the counter electrode for the upper electrode 160, to prevent a plasma density being non-uniform.

A frame supporter 140 is formed at an inner sidewall of the chamber 110. The frame supporter 140 functions as a supporter for the substrate support frame 130. Accordingly, there is no limitation for a shape or a number of the frame supporter 140 as long as the frame supporter 140 supports the substrate support frame 130 and does not obstruct a movement of the susceptor 120. A height of the frame support 140 corresponds to the substrate in/out port (not shown) at a sidewall of the chamber 110 to make convenient to input or output the substrate S.

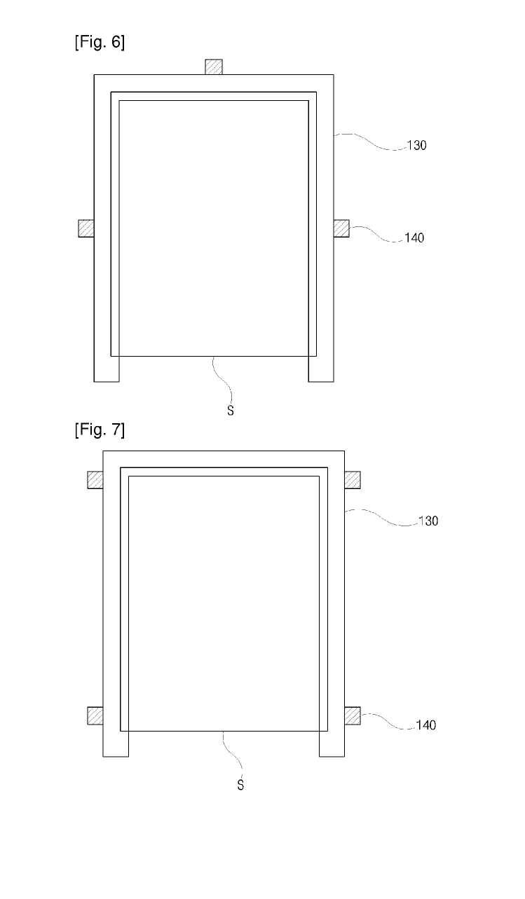

Two embodiments for the frame supporter are described with FIGS. 6 and 7. In FIG. 6, there are three frame supporter 140. Each of the three frame supporter 140 is located to correspond to each side of the substrate support frame 130. On the other hand, in FIG. 7, there are four frame supporter 140. Two of the four frame supporter 140 are located a side of the substrate support frame 130, and the other two of the four frame supporter 140 are located an opposite side of the substrate support frame 130.

Referring again to FIG. 2, the susceptor 120 may include a strengthen portion 126. The strengthen portion 126 may be formed of a ceramic material. When the susceptor 120 contacts the leg 133 of the substrate support frame 130, a portion 120 of the susceptor 120 or an anodized film of the leg 133 may wear down such that electrical isolation between the substrate support frame 130 and the susceptor 120 is up set. The strengthen portion 126 of a material having a anti-abrasion property, such as ceramic, prevents the above problem. The strengthen portion 126 is disposed in the susceptor 120 or on the susceptor 120. In any case, when the leg 133 contacts the strengthen portion 126, the susceptor 120 should contact the substrate S.

Referring to FIG. 4, which shows the substrate disposed on the edge portion of substrate support frame, the substrate S contacts the edge portion 132 of the substrate support frame 130 as much as a width W. The width W may be about 3 millimeter (mm) to about 10 mm. When the width is too narrow, the substrate S may have an unstable position. On the contrary, when the width is too broad, problems, for example, non-uniform coating thickness at boundary portion, occur because of temperature deviation between the substrate support frame 130 and the susceptor 120 (of FIG. 2). It is because a heater (not shown) is disposed in the susceptor 120 to heat the substrate S.

In FIG. 4, a portion between an upper surface of the edge portion 132 and an upper surface of the body 131 is inclined to them. There is an advantage for aligning the substrate S onto the substrate support frame 130.

On the other hand, a portion between an upper surface of the edge portion 132 and an upper surface of the body 131 is vertical to them. There is an advantage for preventing a thin film from being formed at side surface of the substrate S.

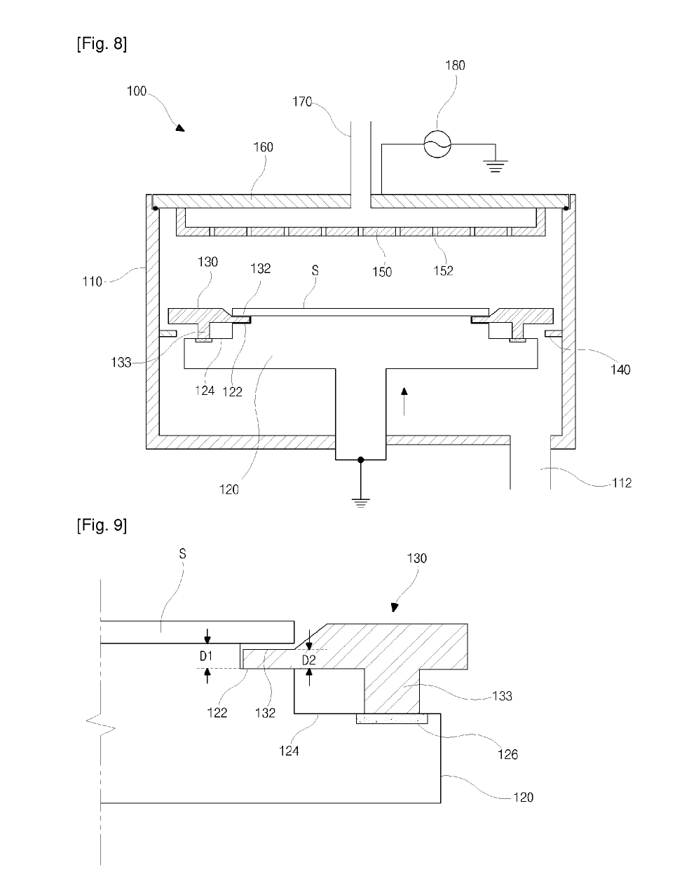

FIG. 8 is a cross-sectional view of a substrate processing apparatus according to the present invention when a susceptor moves upward. A center portion of the susceptor 120 contacts a bottom surface of the substrate S, a first outer portion 122 of the susceptor 120 contacts a bottom surface of the edge portion 132, and a second outer portion 124 of the susceptor 120 contacts a bottom surface of the leg 133. Since an upper surface of the center portion of the susceptor 120 contacts and pushes up the substrate S when the susceptor moves upward, a height of the first outer portion 122 is greater than that of the second outer portion 124 and smaller than that of the center portion of the susceptor 120.

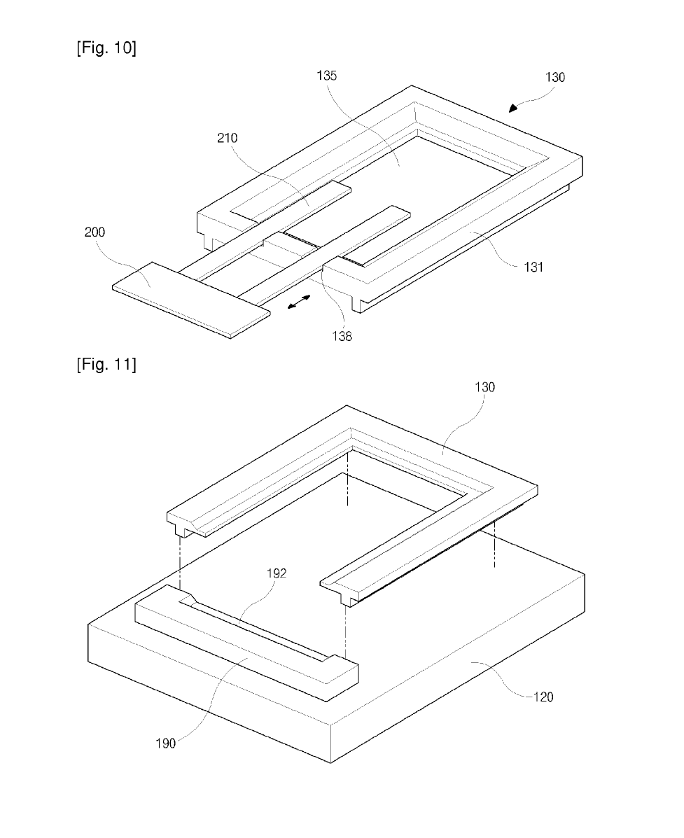

Referring to FIG. 9, which shows a contact portion of a susceptor and a substrate support frame, a thickness D1 of the center portion of the susceptor 120 is equal to or greater than a thickness D2 of the edge portion 132 of the substrate support frame 130. In this case, the thickness D1 of the center portion of the susceptor 120 is defined as a height different between the center portion and the first outer portion 122. If the thickness D1 of the center portion of the susceptor 120 is smaller than the thickness D2 of the edge portion 132 of the substrate support frame 130, the substrate S can not contact the susceptor 120 such that there is a temperature deviation onto the substrate S. As a result, uniformity of a thin film on the substrate can not be achieved.

When the strengthen portion 126 does not protrude from an upper surface of the second outer portion 124, a thickness of the leg 133 is the same as a height difference between the first and second outer portions 122 and 124. On the other hand, when the strengthen portion 126 protrudes from the upper surface of the second outer portion 124, a thickness summation of the leg 133 and the strengthen portion 126 is the same as the height difference between the first and second outer portions 122 and 124. If the leg 133 is not formed, the susceptor 120 does not have the second outer portion 124.

Hereinafter, processes of loading and unloading the substrate are explained with reference to FIGS. 2 to 8. Before the substrate S is not inputted into the chamber 110, the substrate support frame 130 is disposed over the susceptor 120 and supported by the frame supporter 140 at the sidewall of the chamber 110. The substrate S is inputted into the chamber 110 by the robot (not shown) through the substrate in/out port (not shown) and disposed over the first opening 135 of the substrate support frame 130 through the second opening 136 of the substrate support frame 130. Then, the robot (not shown) moves downward such that the substrate S is disposed on the edge portion 132 of the substrate support frame 130. After the robot (not shown) disappears, the inner space of the chamber 110 has a vacuum by a vacuum pump (not shown) through the exhaust hole 112. The susceptor 120 moves upward to a processing location. Namely, the center portion of the susceptor 120 contacts the bottom surface of the substrate S through the first opening 135 of the substrate support frame 130 and pushes up the substrate S with the substrate support frame 130. It is called as a loading process. When the substrate S is disposed at the processing location, a source material is sprayed onto the substrate S through the gas distribution plate 150 and the upper electrode 160 receives a power from the RF power source 180. As a result, plasma, which is a mixture of activated radicals and ions, is generated such that a thin film is deposited on the substrate S.

After a thin film forming process is finished, the susceptor 120 moves downward. While the susceptor moves 120, the body 131 of the substrate support frame 130 is suspended by the frame supporter 140 such that the substrate support frame 130 with the substrate S is separated from the susceptor 120.

Even if the substrate S adheres closely to the susceptor 120 because static electricity, there is no damage on the substrate S when the substrate is detached from the susceptor 120 due to a sufficient thickness of the substrate S.

When the susceptor S moves down to an initial position, the robot (not shown) enters the chamber and is located under the substrate S. Then, the substrate S is pushed up by the robot (not shown) and separated from the substrate support frame 130, and outputted from the chamber 110. It is called as an unloading process.

The above mentioned substrate support frame has an opening at a side surface. However, the opening at the side surface causes a temperature deviation or a plasma density deviation. Accordingly, process uniformity is generated.

A substrate support frame for overcoming the above problem is explained with reference to FIG. 10. In FIG. 10, an opening 135 is surrounded the body 131. Namely, the body 131 includes four side walls without the second opening 136 (of FIG. 3). A groove 138 is formed at one side wall. The substrate is transferred into the opening 135 by a robot 200 through the groove 138. A number of the groove 138 is determined by a number of arms 210 of the robot 200. During loading or unloading, the robot 200 is required to slightly move upward or downward. Accordingly, a depth of the groove 138 is determined depending on a movement of the robot 200.

FIG. 11 shows another embodiment of a substrate support frame. Similar to the substrate support frame in FIG. 3, the substrate support frame 130 in FIG. 11 has two openings and three side wall. Unlike the previously explained embodiment, an auxiliary frame 190 corresponding to a second opening of the substrate support frame 130 is attached on the susceptor 120. While a thin film forming process is performed, an auxiliary edge portion 192 of the auxiliary frame contacts the substrate such that problems, such as a temperature deviation and a plasma density deviation, are perfectly prevented.

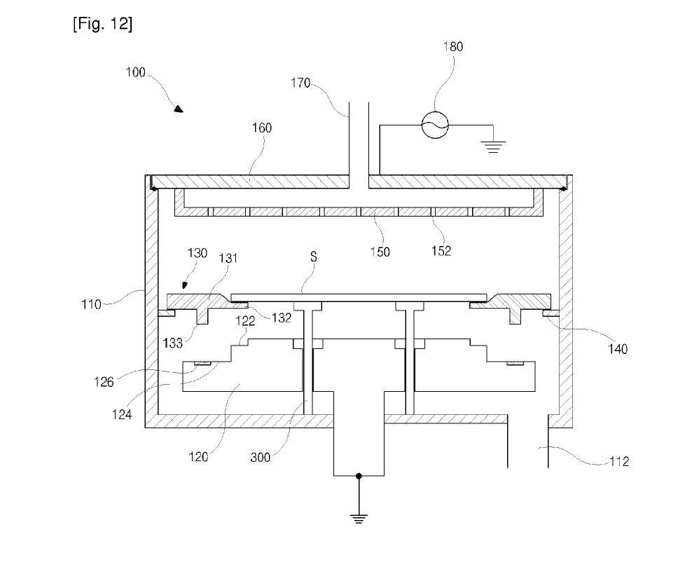

The above mentioned substrate processing apparatus does not have a lift pin. However, to prevent a center portion of the substrate being sunk, the substrate processing apparatus according to the present invention includes not only the substrate support frame but also a lift pin, as shown in FIG. 12. Boundary portion of the substrate S is supported by the substrate support frame 130, while a center portion of the substrate S is supported by the lift pin 300.

It will be apparent to those skilled in the art that various modifications and variations can be made in the apparatus having an edge frame without departing from the spirit or scope of the invention. Thus, it is intended that the present invention covers the modifications and variations of this invention provided they come within the scope of the appended claims and their equivalents.

### INDUSTRIAL APPLICABILITY

In the present invention, productivity is improved because of a substrate support frame contacting a boundary portion of a bottom surface of a substrate. A substrate processing apparatus including the substrate support frame is available for processing a solar cell, wafer and so on.

1. A substrate support frame for loading or unloading a substrate on or from a susceptor in a chamber, wherein the substrate support frame is disposed over the susceptor, comprising:
a body supporting a boundary portion of the substrate;
a leg protruding from the body along the susceptor;
a first opening through a center portion of the body and exposing a center portion of the susceptor; and
a second opening corresponding to one side of the body,
wherein the substrate is disposed on the body through the second opening to overlap the center portion of the susceptor.

2. The frame according to claim 1, wherein the body includes an edge portion protruding from the body into the first opening and being dented from the body, and wherein the substrate contacts the edge portion of the body.

3. The frame according to claim 1, wherein the second opening includes at least one groove at a sidewall of the body.

4. (canceled)

5. The frame according to claim 1, wherein the body includes anodized aluminum.

6. A substrate processing apparatus, comprising:
a chamber having an inner space;
a susceptor in the inner space of the chamber and being movable upward and downward;
an electrode over the susceptor;
a gas distribution plate disposed between the susceptor and the electrode and supplying a source material into the inner space of the chamber; and
a substrate support frame including first and second openings and disposed over the susceptor, the first opening through a center portion of the substrate support frame and exposing a center portion of the susceptor, the second opening corresponding to one side of the substrate support frame,
wherein a substrate is transferred onto the substrate support frame through the second opening, and wherein the substrate is supported by the substrate support frame and pushed up to a processing position with the substrate support frame by the susceptor.

7. The apparatus according to claim 6, wherein the substrate support frame includes a first body and a second body, wherein the second body protrudes from the first body into the first opening and has a smaller height from a bottom surface of the body than the first body, and wherein the substrate contacts the second body.

8. The apparatus according to claim 7, wherein the susceptor includes a first edge portion surrounding the center portion of the susceptor and having a smaller height from a bottom surface of the susceptor than the center portion of the susceptor, wherein a height difference between the center portion of the susceptor and the first edge portion is equal to or greater than a thickness of the second body, and wherein when the susceptor moves upward, the first edge portion contacts the second body of the substrate support frame.

9. The apparatus according to claim 8, wherein the substrate support frame further includes a leg extending from the first body into the susceptor, and the susceptor further includes a second edge portion such that the first edge portion is disposed between the center portion of the susceptor and the second edge portion, wherein when the susceptor moves upward, the second edge portion contacts the leg.

10. The apparatus according to claim 9, further comprising a counter pattern contacting the second edge portion and corresponding to the leg such that the susceptor is electrically isolated from the leg.

11. The apparatus according to claim 6, further comprising a lift pin through the susceptor and corresponding to the first opening of the substrate support frame, wherein a height of the lift pin from a bottom surface of the chamber is the same as a height of the substrate support frame.

12. The apparatus according to claim 6, further comprising an auxiliary frame disposed on the susceptor and corresponding to the second opening.

13. The apparatus according to claim 6, further comprising a frame supporter at an inner sidewall of the chamber to support the substrate support frame over the susceptor.

14. The apparatus according to claim 7, wherein the substrate support frame is insulated from the susceptor.

15. The apparatus according to claim 14, wherein the substrate support frame includes anodized aluminum.

16. A method of loading the substrate on the susceptor using the substrate processing apparatus of claim 6, comprising:
disposing the substrate on the substrate support frame, wherein a boundary portion of the substrate contacts the substrate support frame, and a center portion of the substrate corresponds to the first opening; and
moving the susceptor upward such that the substrate support frame with the substrate is located at a pre-determined position,
wherein when the susceptor moves upward, a center portion of the susceptor contacts the center portion of the substrate through the first opening.

17. A method of unloading the substrate from the susceptor using the substrate processing apparatus of claim 6, comprising:
moving the susceptor downward such that the substrate support frame with the substrate is disposed on a frame supporter at an inner sidewall of the chamber to be separated from the susceptor;
separating the substrate from the substrate support frame; and
transferring the substrate from the chamber into an outside of the chamber.
